(19) United States
(12) Patent Application Publication
(10) Pub. No.: US 2019/0247944 A1
(43) Pub. Date: Aug. 15, 2019

(54) FLUX TRANSFER METHOD

(71) Applicant: POWERTECH TECHNOLOGY INC., Hsinchu County (TW)

(72) Inventors: Kun-Chi Hsu, HSINCHU COUNTY (TW); Sheng-Tou Tseng, HSINCHU COUNTY (TW); Hung-Chieh Huang, HSINCHU COUNTY (TW)

(21) Appl. No.: 15/893,684

(22) Filed: Feb. 11, 2018

(51) Int. Cl. B23K 1/20; B23K 3/08

(52) U.S. Cl. CPC B23K 1/203; H05K 3/3489; B23K 3/082

(57) ABSTRACT

A flux transfer tool includes a frame, a plunger, a baseplate, a flux supplier and a driving mechanism. The frame has a chamber. The plunger is movably disposed in the chamber. The baseplate is mounted on the frame. The baseplate has a plurality of holes formed thereon. The flux supplier is connected to the frame and contains a flux. The flux supplier supplies the flux to the chamber between the plunger and the baseplate. The driving mechanism is disposed on the frame. The driving mechanism drives the plunger to move towards the baseplate to squeeze the flux out of the holes of the baseplate. The driving mechanism drives the plunger to move away from the baseplate to keep the flux in the chamber.

### BACKGROUND OF THE INVENTION

### 1. Field of the Invention

The invention relates to a flux transfer tool and a flux transfer method and, more particularly, to a flux transfer tool and a flux transfer method for improving a flux transfer process of a ball grid array (BGA) package and chip scale package (CSP).

### 2. Description of the Prior Art

BGA and CSP techniques have become more common in recent years for connecting high-density IC components onto circuit boards. In BGA and CSP techniques, a flux transfer tool is used to transfer flux to a plurality of bond pads of a substrate to remove oxidized film and to provisionally fix solder balls before the solder balls are mounted on the bond pads by a reflow process.

Referring to FIGS. 1 to 3, FIG. 1 is a side view illustrating a flux transfer tool 1 of the prior art, FIG. 2 is a side view illustrating the flux transfer pins 10 adhered with the flux 12, and FIG. 3 is a side view illustrating the flux 12 transferred from the flux transfer pins 10 to the bond pads 20 of the substrate 2. As shown in FIG. 1, the flux transfer tool 1 comprises a plurality of flux transfer pins 10. A flux 12 in a flux tray 14 is extended to a uniform thickness by means of a scraper 16. Then, the flux transfer tool 1 is driven to move towards the flux tray 14, such that the flux 12 adheres to the flux transfer pins 10 uniformly, as shown in FIG. 2. Then, the flux transfer tool 1 is driven to move to a position above a substrate 2 and move towards the substrate 2, such that the flux 12 is transferred from the flux transfer pins 10 to a plurality of bond pads 20 of the substrate 2, as shown in FIG. 3.

As demand for electronic devices that are smaller and more powerful continues to increase, the size of the solder ball and the pitch between two adjacent solder balls in a BGA and CSP package become smaller and smaller accordingly. However, due to the limitation of the spacing S between two adjacent flux transfer pins 10, the size of the solder ball cannot be smaller than about 0.15 mm and the pitch between two adjacent solder balls cannot be smaller than about 0.3 mm, such that the development of the electronic devices is limited.

### SUMMARY OF THE INVENTION

The invention provides a flux transfer tool and a flux transfer method for improving a flux transfer process of a BGA and CSP package, so as to solve the aforesaid problems.

According to an embodiment of the invention, a flux transfer tool comprises a frame, a plunger, a baseplate, a flux supplier and a driving mechanism. The frame has a chamber. The plunger is movably disposed in the chamber. The baseplate is mounted on the frame. The baseplate has a plurality of holes formed thereon. The flux supplier is connected to the frame and contains a flux. The flux supplier supplies the flux to the chamber between the plunger and the baseplate. The driving mechanism is disposed on the frame. The driving mechanism drives the plunger to move towards the baseplate to squeeze the flux out of the holes of the baseplate. The driving mechanism drives the plunger to move away from the baseplate to keep the flux in the chamber.

According to another embodiment of the invention, a flux transfer method comprises steps of moving a flux transfer tool to a position above a substrate, wherein the substrate has a plurality of bond pads, the flux transfer tool comprises a frame, a plunger, a baseplate, a flux supplier and a driving mechanism, the frame has a chamber, the plunger is movably disposed in the chamber, the baseplate is mounted on the frame, the baseplate has a plurality of holes formed thereon and arranged corresponding to the bond pads of the substrate, the flux supplier is connected to the frame and contains a flux, and the driving mechanism is disposed on the frame; supplying the flux to the chamber between the plunger and the baseplate by the flux supplier; driving the plunger to move towards the baseplate to squeeze the flux out of the holes of the baseplate by the driving mechanism, such that the flux is formed on the bond pads of the substrate; and driving the plunger to move away from the baseplate to keep the flux in the chamber by the driving mechanism.

As mentioned in the above, the invention utilizes the baseplate to transfer the flux from the chamber of the frame to the bond pads of the substrate and utilizes the driving mechanism to control the output amount of the flux. Since the holes on the baseplate can be adjusted in accordance with the size of the solder ball and the pitch between two adjacent solder balls, the BGA and CSP package can be miniaturized according to practical demand. Accordingly, the invention can improve the flux transfer process of the BGA and CSP package and save the cost of manufacturing the flux transfer pin of the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a side view illustrating a flux transfer tool of the prior art.

FIG. 2 is a side view illustrating the flux transfer pins adhered with the flux.

FIG. 3 is a side view illustrating the flux transferred from the flux transfer pins to the bond pads of the substrate.

FIG. 4 is a side view illustrating a flux transfer tool according to an embodiment of the invention.

FIG. 5 is a side view illustrating the flux supplier supplying the flux to the chamber between the plunger and the baseplate.

FIG. 6 is a side view illustrating the plunger squeezing the flux out of the holes of the baseplate.

FIG. 7 is a side view illustrating the flux kept in the chamber.

FIG. 8 is a flowchart illustrating a flux transfer method according to an embodiment of the invention.

FIG. 9 is a side view illustrating a flux transfer tool according to another embodiment of the invention.

FIG. 10 is a side view illustrating a flux transfer tool according to another embodiment of the invention.

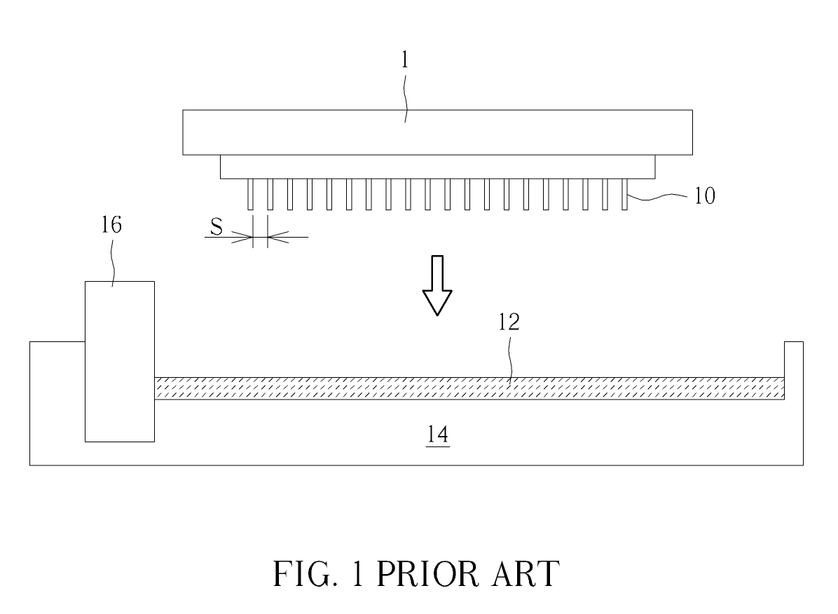

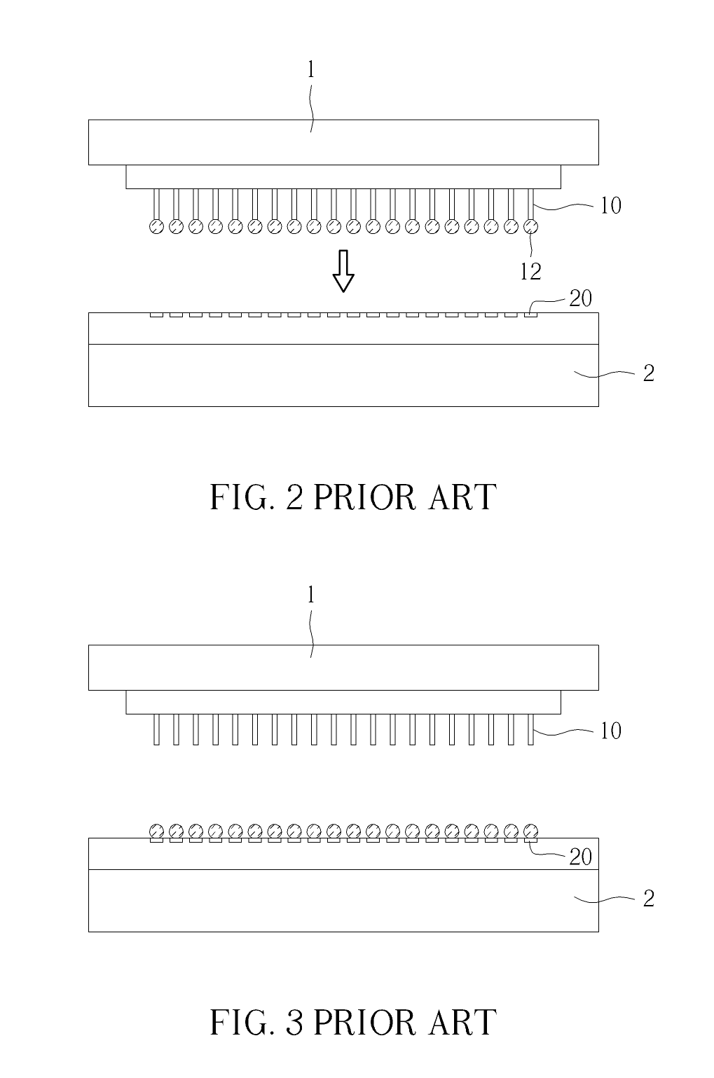

### DETAILED DESCRIPTION

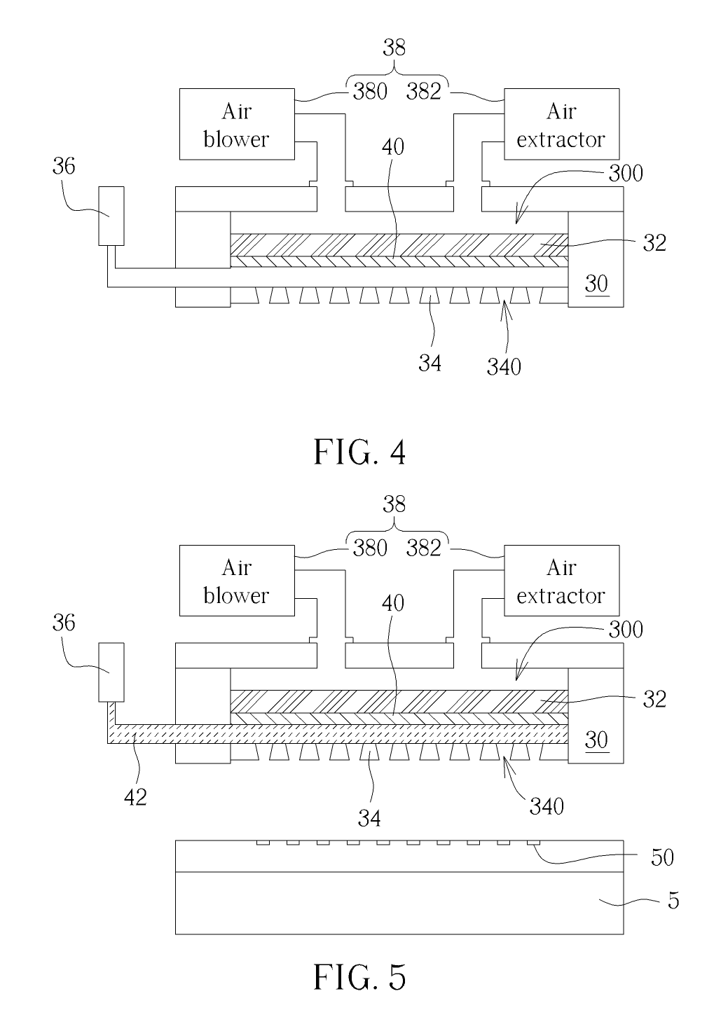

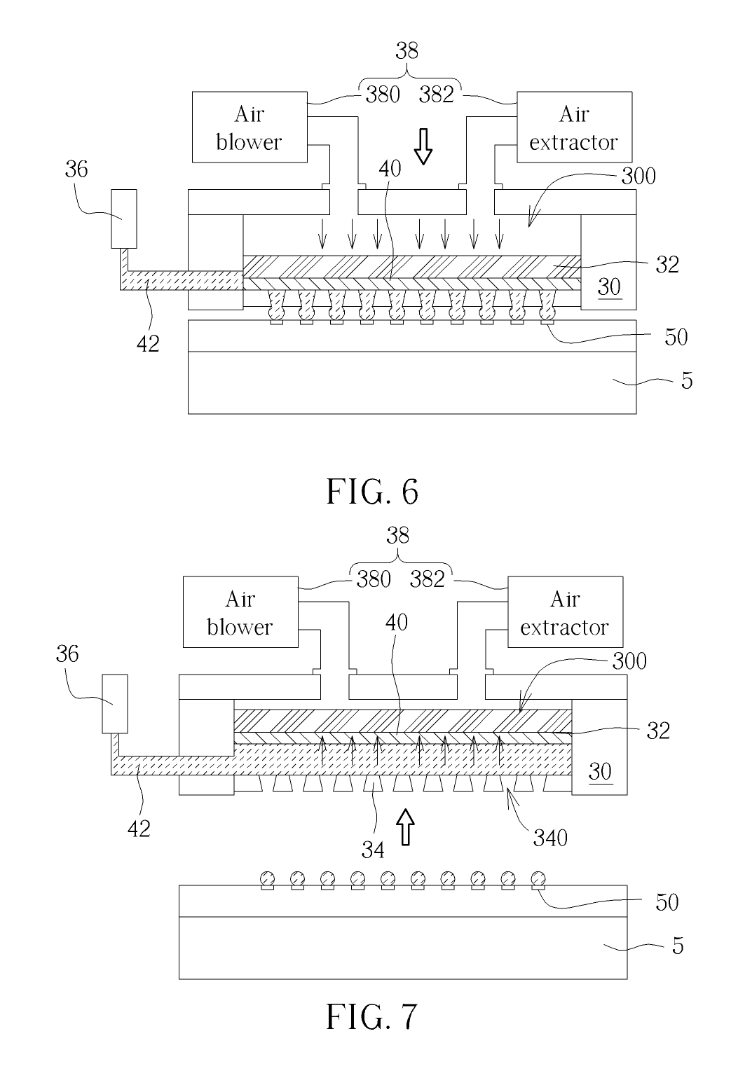

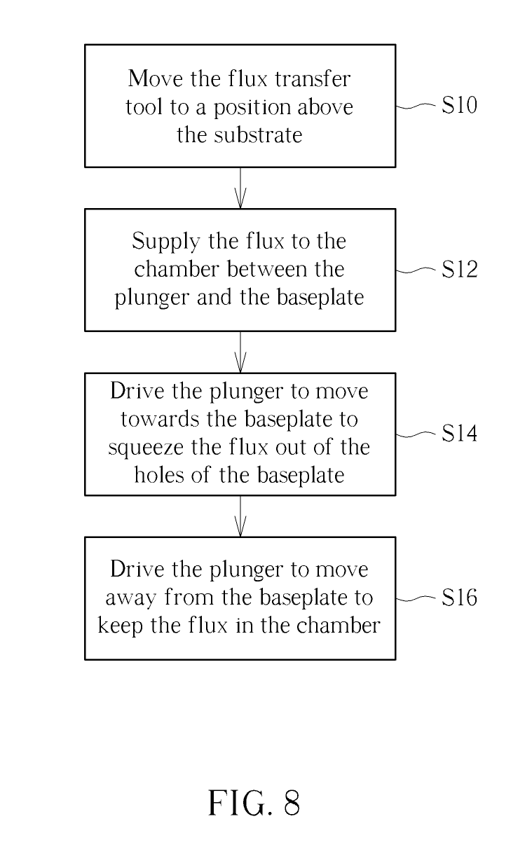

Referring to FIGS. 4 to 8, FIG. 4 is a side view illustrating a flux transfer tool 3 according to an embodiment of the invention, FIG. 5 is a side view illustrating the flux supplier 36 supplying the flux 42 to the chamber 300 between the plunger 32 and the baseplate 34, FIG. 6 is a side view illustrating the plunger 32 squeezing the flux 42 out of the holes 340 of the baseplate 34, FIG. 7 is a side view illustrating the flux 42 kept in the chamber 300, and FIG. 8 is a flowchart illustrating a flux transfer method according to an embodiment of the invention.

As shown in FIGS. 4 to 7, the flux transfer tool 3 comprises a frame 30, a plunger 32, a baseplate 34, a flux supplier 36, a driving mechanism 38, and a flexible member 40. The frame 30 has a chamber 300. The plunger 32 is movably disposed in the chamber 300 of the frame 30. The baseplate 34 is mounted on the frame 30 and the baseplate 34 has a plurality of holes 340 formed thereon. In this embodiment, the baseplate 34 may be, but not limited to, a stencil. The flux supplier 36 is connected to the frame 30 and contains a flux 42. The driving mechanism 38 is disposed on the frame 30. In this embodiment, the driving mechanism 38 may comprise an air blower 380 and an air extractor 382, but is not so limited. The flexible member 40 is disposed on the plunger 32 and abuts against an inner wall of the frame 30. In this embodiment, the flexible member 40 may be made of, but not limited to, rubber.

As shown in FIGS. 5 to 7, the flux transfer tool 3 is used to transfer the flux 42 from the chamber 300 of the frame 30 to a substrate 5. The substrate 5 may be an IC package or the like. The substrate 5 has a plurality of bond pads 50 and the holes 340 of the baseplate 34 are arranged corresponding to the bond pads 50 of the substrate 5.

To transfer the flux 42 from the chamber 300 of the frame 30 to the substrate 5, first, the flux transfer tool 3 moves to a position above the substrate 5, as shown in FIG. 5 and step S10 in FIG. 8. Then, the flux supplier 36 supplies the flux 42 to the chamber 300 between the plunger 32 and the baseplate 34, as shown in FIG. 5 and step S12 in FIG. 8.

Then, the flux transfer tool 3 moves towards the substrate 5 and the driving mechanism 38 drives the plunger 32 to move towards the baseplate 34 to squeeze the flux 42 out of the holes 340 of the baseplate 34, such that the flux 42 is formed on the bond pads 50 of the substrate 5, as shown in FIG. 6 and step S14 in FIG. 8. In this embodiment, the air blower 380 of the driving mechanism 38 can blow air into the chamber 300 to drive the plunger 32 to move towards the baseplate 34, so as to squeeze the flux 42 out of the holes 340 of the baseplate 34. Furthermore, the invention can control the air pressure generated by the air blower 380 to adjust the output amount of the flux 42.

After forming the flux 42 on the bond pads 50 of the substrate 5, the flux transfer tool 3 moves away from the substrate 5 and the driving mechanism 38 drives the plunger 32 to move away from the baseplate 34 to keep the flux 42 in the chamber 300, as shown in FIG. 7 and step S16 in FIG. 8. In this embodiment, the air extractor 382 of the driving mechanism 38 can extract air from the chamber 300 to vacuumize the chamber 300, so as to drive the plunger 32 to move away from the baseplate 34. Consequently, the flux 42 can be kept in the chamber 300.

In this embodiment, the holes 340 on the baseplate 34 can be adjusted in accordance with the size of the solder ball and the pitch between two adjacent solder balls, so the BGA and CSP package can be miniaturized according to practical demand. Accordingly, the invention can improve the flux transfer process of the BGA and CSP package and save the cost of manufacturing the flux transfer pin of the prior art.

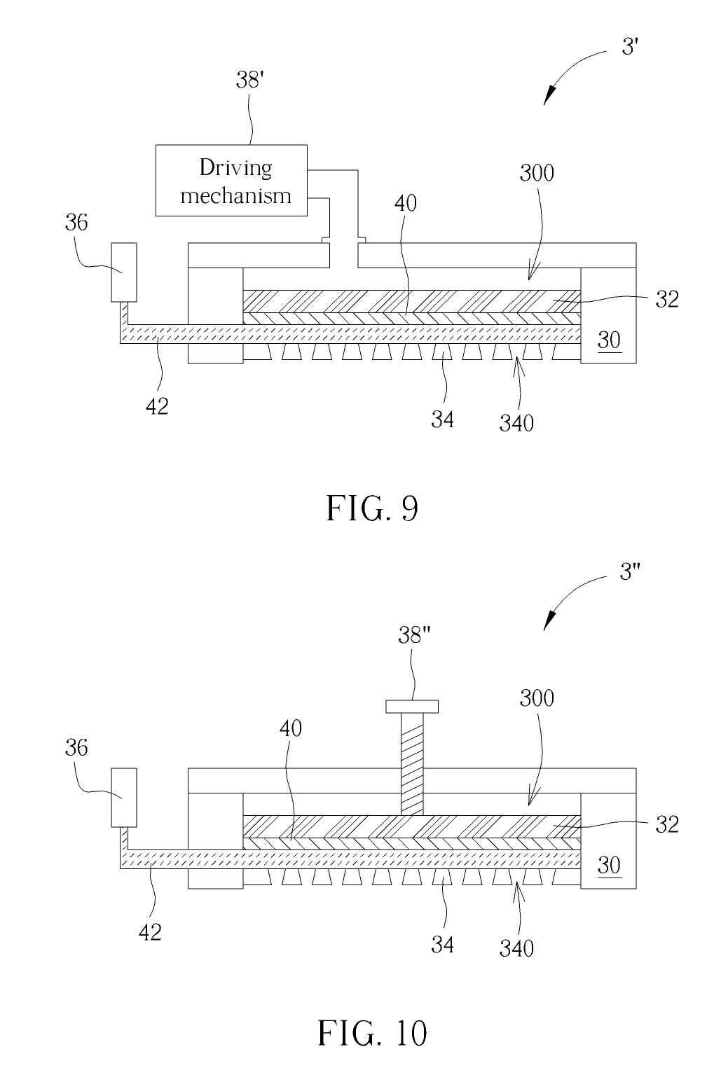

FIG. 9 is a side view illustrating a flux transfer tool 3′ according to another embodiment of the invention. The main difference between the flux transfer tool 3′ and the aforesaid flux transfer tool 3 is that the driving mechanism 38′ of the flux transfer tool 3′ is an air controller, as shown in FIG. 9. Accordingly, in this embodiment, the air controller (i.e. the driving mechanism 38′) can blow air into the chamber 300 to drive the plunger 32 to move towards the baseplate 34, so as to squeeze the flux 42 out of the holes 340 of the baseplate 34. On the other hand, the air controller (i.e. the driving mechanism 38′) can extract air from the chamber 300 to vacuumize the chamber 300, so as to drive the plunger 32 to move away from the baseplate 34. Consequently, the flux 42 can be kept in the chamber 300.

FIG. 10 is a side view illustrating a flux transfer tool 3″ according to another embodiment of the invention. The main difference between the flux transfer tool 3″ and the aforesaid flux transfer tool 3 is that the driving mechanism 38″ of the flux transfer tool 3″ is a lifting screw rod connected to the plunger 32, as shown in FIG. 10. Accordingly, in this embodiment, the lifting screw rod (i.e. the driving mechanism 38′ can rotate in a first direction to drive the plunger 32 to move towards the baseplate 34, so as to squeeze the flux 42 out of the holes 340 of the baseplate 34. On the other hand, the lifting screw rod (i.e. the driving mechanism 38″) can rotate in a second direction to drive the plunger 32 to move away from the baseplate 34, so as to keep the flux 42 in the chamber 300. It should be noted that the first direction is opposite to the second direction. For example, the first direction may be clockwise and the second direction may be counterclockwise, or alternatively, the first direction may be counterclockwise and the second direction may be clockwise.

As mentioned in the above, the invention utilizes the baseplate to transfer the flux from the chamber of the frame to the bond pads of the substrate and utilizes the driving mechanism to control the output amount of the flux. Since the holes on the baseplate can be adjusted in accordance with the size of the solder ball and the pitch between two adjacent solder balls, the BGA and CSP package can be miniaturized according to practical demand. Accordingly, the invention can improve the flux transfer process of the BGA and CSP package and save the cost of manufacturing the flux transfer pin of the prior art.

Those skilled in the art will readily observe that numerous modifications and alterations of the device and method may be made while retaining the teachings of the invention. Accordingly, the above disclosure should be construed as limited only by the metes and bounds of the appended claims.

1. A flux transfer tool comprising:
a frame having a chamber;
a plunger movably disposed in the chamber;
a baseplate mounted on the frame, the baseplate having a plurality of holes formed thereon;
a flux supplier connected to the frame and containing a flux, the flux supplier supplying the flux to the chamber between the plunger and the baseplate; and
a driving mechanism disposed on the frame, the driving mechanism driving the plunger to move towards the baseplate to squeeze the flux out of the holes of the baseplate, the driving mechanism driving the plunger to move away from the baseplate to keep the flux in the chamber.

2. The flux transfer tool of claim 1, wherein the driving mechanism comprises an air blower and an air extractor, the air blower blows air into the chamber to drive the plunger to move towards the baseplate, and the air extractor extracts air from the chamber to drive the plunger to move away from the baseplate.

3. The flux transfer tool of claim 1, wherein the driving mechanism is an air controller, the air controller blows air into the chamber to drive the plunger to move towards the baseplate, and the air controller extracts air from the chamber to drive the plunger to move away from the baseplate.

4. The flux transfer tool of claim 1, wherein the driving mechanism is a lifting screw rod connected to the plunger, the lifting screw rod rotates in a first direction to drive the plunger to move towards the baseplate, and the lifting screw rod rotates in a second direction to drive the plunger to move away from the baseplate, the first direction is opposite to the second direction.

5. The flux transfer tool of claim 1, further comprising a flexible member disposed on the plunger and abutting against an inner wall of the frame.

6. The flux transfer tool of claim 1, wherein the holes of the baseplate are arranged corresponding to a plurality of bond pads of a substrate.

7. A flux transfer method comprising steps of:
moving a flux transfer tool to a position above a substrate, wherein the substrate has a plurality of bond pads, the flux transfer tool comprises a frame, a plunger, a baseplate, a flux supplier and a driving mechanism, the frame has a chamber, the plunger is movably disposed in the chamber, the baseplate is mounted on the frame, the baseplate has a plurality of holes formed thereon and arranged corresponding to the bond pads of the substrate, the flux supplier is connected to the frame and contains a flux, and the driving mechanism is disposed on the frame;
supplying the flux to the chamber between the plunger and the baseplate by the flux supplier;
driving the plunger to move towards the baseplate to squeeze the flux out of the holes of the baseplate by the driving mechanism, such that the flux is formed on the bond pads of the substrate; and
driving the plunger to move away from the baseplate to keep the flux in the chamber by the driving mechanism.

8. The flux transfer method of claim 7, wherein the driving mechanism comprises an air blower and an air extractor, the flux transfer method comprising steps of:
blowing air into the chamber to drive the plunger to move towards the baseplate by the air blower; and
extracting air from the chamber to drive the plunger to move away from the baseplate by the air extractor.

9. The flux transfer method of claim 7, wherein the driving mechanism is an air controller, the flux transfer method comprising steps of:
blowing air into the chamber to drive the plunger to move towards the baseplate by the air controller; and
extracting air from the chamber to drive the plunger to move away from the baseplate by the air controller.

10. The flux transfer method of claim 7, wherein the driving mechanism is a lifting screw rod connected to the plunger, the flux transfer method comprising steps of:
rotating the lifting screw rod in a first direction to drive the plunger to move towards the baseplate; and
rotating the lifting screw rod in a second direction to drive the plunger to move away from the baseplate, wherein the first direction is opposite to the second direction.
